(19) United States
(12) Patent Application Publication
(10) Pub. No.: US 2023/0115177 A1
(43) Pub. Date: Apr. 13, 2023

(54) COMPRESSIBLE TRAY FOR SOLID CHEMICAL VAPORIZING CHAMBER

(71) Applicant: ENTEGRIS, INC., Billerica, MA (US)

(72) Inventors: Scott L. Battle, Cedar Park, TX (US); Donn K. Naito, Meadowlakes, TX (US); John N. Gregg, Marble Falls, TX (US); Jacob Thomas, Leander, TX (US); Chase Parker, Burnet, TX (US); James Schindler, Lampasas, TX (US); Bryan C. Hendrix, Danbury, CT (US); Benjamin H. Olson, Florence, TX (US)

(21) Appl. No.: 17/961,457

(22) Filed: Oct. 6, 2022

Related U.S. Application Data
(60) Provisional application No. 63/253,800, filed on Oct. 8, 2021.

(51) Int. Cl. C23C 16/448; C23C 16/455

(52) U.S. Cl. CPC C23C 16/4481; C23C 16/45544

(57) ABSTRACT

A tray for an ampoule of a delivery system of solid precursor materials used in Atomic Layer Deposition (ALD) processes, Chemical Vapor Deposition (CVD) processes or both. The tray is configured to be able to have a reduced profile size when compressed to enhance the ease of which the tray can be inserted into the ampoule, and the tray is configured to expand in size to make improved contact with inner wall surfaces of the ampoule to provide improved heat transfer from the inner wall to the tray and ultimately to the solid precursor materials disposed on the tray.

### PRIORITY

This disclosure claims priority to U.S. Provisional Patent No. 63/253,800, with a filing date of Oct. 8, 2021. The priority document is incorporated herein for all purposes.

### FIELD

This disclosure relates generally to delivery systems of solid precursor materials used in Atomic Layer Deposition (ALD) processes, Chemical Vapor Deposition (CVD) processes or both.

### BACKGROUND

A delivery system designed for transport of solid precursor materials used in ALD and CVD processes are used in manufacturing processes of wafers. Such systems can include ampoules configured to contain solid precursor materials.

### SUMMARY

Some embodiments of a delivery system include an ampoule having a body which defines an interior chamber with inner surface(s). At least some of these embodiments of the delivery system are used in ALD, CVD, or both processes. Solid precursor materials can be used in fabrication of microelectronic devices. In some embodiments, the solid precursor materials are a variety of organic precursors, inorganic precursors, metal organic precursors, or combination(s) thereof. In some embodiments, heat is required to use the solid precursor materials

In some embodiments, the ampoule includes, in its inner chamber, at least one tray for holding the solid precursor materials. In some embodiments, the trays are configured with passageways for flowing a fluid, such as a gas, from bottom of the inner chamber to the top of the inner chamber, from the top of the inner chamber to the bottom of the inner chamber, or both.

In some embodiments, the tray is configured to conduct heat from the inner surface(s) of the interior chamber to the solid precursor materials. In some embodiments, the tray is configured with at least a portion to push a part of the tray to increase or maximize the contact with the inner surface(s) of the interior chamber. In some embodiments, the tray is configured with a portion that increases or maximizes the heat transfer from the inner surface(s) of the interior chamber to another part of the tray, the solid precursor materials, or both.

In some embodiments, the tray is configured to with a structure which allows for the tray to change its structure so that it can be placed in the inner chamber with ease or relative eases, and when placed within the inner chamber, it is configured to change its structure to hold fast within the inner chamber. According to some embodiments, the tray can have portion(s) that engage, contact, connect to, or any combination thereof, to the inner surface or other parts of the inner chamber in a mechanical way, frictional way, or both.

In some embodiments, a tray for an ampoule comprises a compressible portion having a compressed state and a relaxed state, wherein a spring potential energy in the compressible portion is higher than in the relaxed state.

In some embodiments of the tray, the tray comprises a heat-transfer component, wherein the heat-transfer component is in thermal contact with the compressible portion.

In some embodiments of the tray, the tray comprises a second heat-transfer component, wherein the second heat-transfer component is in thermal contact with the compressible portion.

In some embodiments of the tray, a distance from the heat-transfer component to the second heat-transfer component is reduced when the compressible portion is compressed.

In some embodiments of the tray, the heat-transfer component and the second heat-transfer component are configured to be in thermal contact with an inner wall surface of the ampoule, and the heat-transfer component and the second heat-transfer component are configured to transfer thermal energy from the inner wall surface of the ampoule to the compressible portion.

In some embodiments of the tray, the tray comprises a surface, wherein the surface is configured to hold solid precursor materials, and the surface is in thermal contact with the compressible portion.

In some embodiments of the tray, the compressible portion is compressible along a radial direction of the surface, a circumferential portion of the surface, or both.

In some embodiments of the tray, the surface includes a non-planar portion, a planar portion, or both.

In some embodiments of the tray, the compressible portion comprises a spring.

In some embodiments of the tray, the compressible portion comprises an accordion-like surface having a ridge direction and a fold direction.

In some embodiments of the tray, the accordion-like surface is configured to hold solid precursor materials.

In some embodiments of the tray, the compressible portion comprises an open-ring.

In some embodiments of the tray, the tray comprises a surface, wherein the surface is configured to hold solid precursor materials, and the surface is in thermal contact with the open-ring.

In some embodiments of the tray, the open-ring is disposed at an outer perimeter of the surface.

In some embodiments of the tray, the open-ring is disposed above the surface.

In some embodiments of the tray, the open-ring is disposed below the surface.

In some embodiments of the tray, the try comprises a second surface, wherein the second surface is configured to hold solid precursor materials, and wherein the second surface is in thermal contact with the open-ring.

In some embodiments of the tray, a distance from the surface and the second surface is reduced when the compressible portion is compressed.

In some embodiments, an ampoule comprises the tray according to any of the embodiments of the tray herein.

In some embodiments, a method of inserting a tray into an ampoule comprises obtaining the tray according to any of the embodiments of the tray described herein; compressing the compressible portion of the tray; and inserting the tray into an inner volume of the ampoule.

In some embodiments, the method further comprises releasing the compressible portion of the tray, wherein the compressible portion expands and the tray is configured to be in thermal contact with an inner wall surface of the ampoule.

### BRIEF DESCRIPTION OF THE DRAWINGS

References are made to the accompanying drawings that form a part of this disclosure and that illustrate embodiments in which the systems and methods described in this Specification can be practiced. Like reference numbers represent the same or similar parts throughout.

FIG. 1 shows a schematic cross-sectional view of an ampoule containing trays according to some of the embodiments.

FIG. 2 shows a tray according to some of the embodiments.

FIGS. 3A-3D show various views of a tray according to some of the embodiments.

FIGS. 4A-4D show various views of a tray according to some of the embodiments.

FIGS. 5A and 5B show various views of a tray according to some of the embodiments.

FIG. 6 shows an exploded view of a tray according to some of the embodiments.

FIG. 7 shows a snap ring for a tray according to some of the embodiments.

FIG. 8 shows a tray according to some of the embodiments.

FIG. 9 shows a flowchart according to some of the embodiments of the methods for inserting a compressible tray into an ampoule of a system.

### DETAILED DESCRIPTION

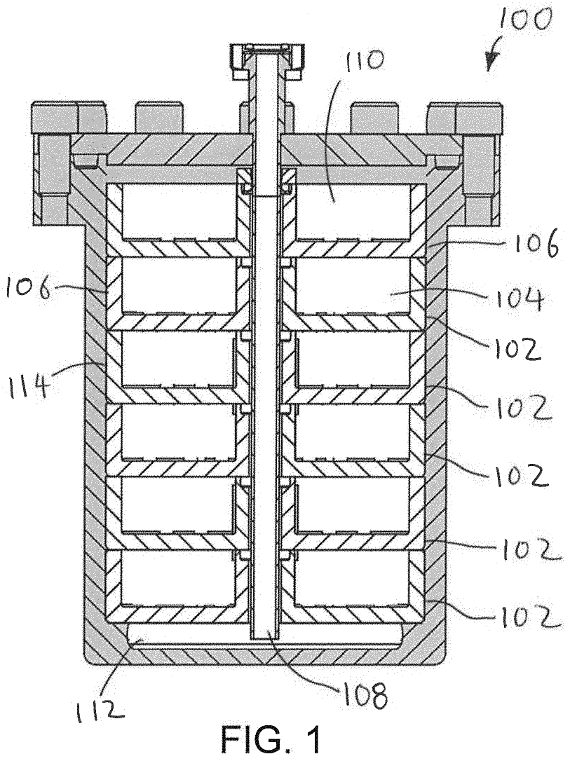

FIG. 1 shows a schematic cross-sectional view of an exemplary ampoule 100 according to some embodiments. The ampoule 100 contains trays 102 according to any of the embodiments described herein in any combination. The ampoule 100 has an inner chamber 104 which defines an inner volume sufficient for holding a stack of trays 102 and also allow for flow of a fluid (e.g., gas) within the inner volume. As shown in FIG. 1, the inner chamber 104 and its volume is generally cylindrical in shape.

The trays 102 may be stainless steel, aluminum, graphite, or other material known to persons of skill in the art. In some embodiments, the tray 102 includes a coating. The coating may provide useful properties to the tray 102. For example, the coating may reduce the amount of metal particles provided from the tray 102 to the associated tool receiving the precursor. In an embodiment, the coating is a ceramic (e.g., aluminum oxide) or a polymer (e.g., polytetrafluoroethylene).

The inner chamber 104 has an inner wall surface 106. Each of the trays 102 is configured to be stackable and sized to be contained within the inner volume of the inner chamber 104. The inner chamber 104 includes flow path(s) 108 for flowing a fluid (e.g., gas) upwards towards the top 110 of the inner chamber 104, downwards towards the bottom 112 of the inner chamber 104, or both. The trays 102 are also each configured to allow the flow of fluid upwards, downwards, or both. For example, each of the trays 102 can have perforations or holes through the body of the tray 102.

Each tray 102 has a portion 114 configured to be in contract with the inner wall surface 106. Increasing the area of surface-to-surface contact of the portion 114 with the inner wall surface 106 enhances heat transfer from the inner wall surface 106 to the tray 102, and thus, enhances heat transfer to the solid precursor materials.

Because the diameter of the inner chamber 104 generally does not change, the tray 102 which has a smaller profile size compared to the diameter of the inner chamber 104, can make the process of inserting the trays and stacking them in the inner chamber 104 relatively easy. However, a tray with static and constant smaller profile size would not be able to make sufficient contact with the inner wall surface 106 of the ampoule 100 to provide good heat transfer from the inner wall surface 106 to the tray and/or the solid precursor materials disposed on the tray.

The embodiments of the trays 102 disclosed herein can achieve both advantages of being able to have a reduced profile size when compressed to enhances the ease of which the tray 102 can be inserted into the inner chamber 104, and then expand in size to make improved contact with the inner wall surface 106 of the ampoule 100 to provide good heat transfer from the inner wall surface 106 to the tray 102 and/or the solid precursor materials disposed on the tray 102. Various exemplary embodiments of the trays 102 are described below.

The term “compressible” as used herein means a configuration of a structure, a material, or both, that is designed to be able to alter, change, shorten, lengthen, or any combination thereof, a device or a portion of a device's linear length, radial length, diametric length, circumferential length, or any combination thereof. Examples of a compressible structure includes one or more of a spring, accordion-like structure, open-ring, mechanical joints with or without a locking mechanism(s), malleable material, porous material, etc.

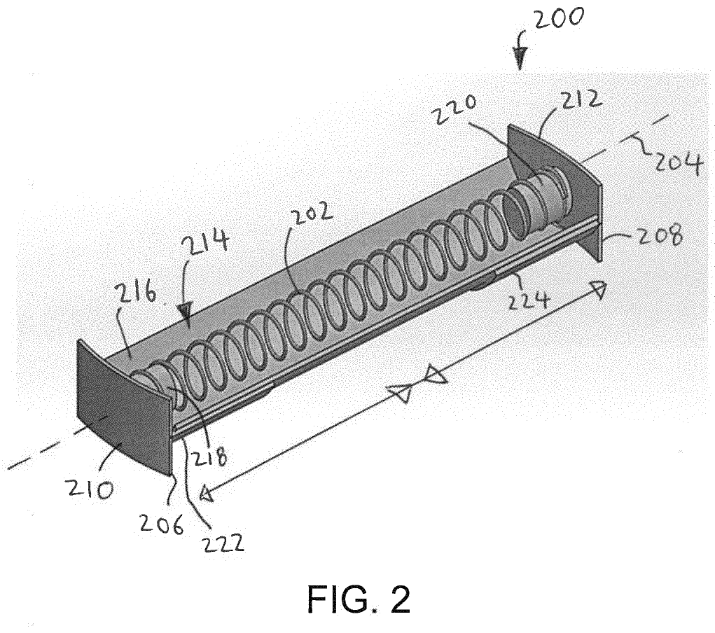

FIG. 2 shows a tray 200 according to some of the embodiments. The tray 200 is configured to stack with other same or similar trays. the tray 200 includes a compressible portion 202, which includes a spring 202 configured to be able to reduce a length along an axial direction. When compressed, the tray 200 can be inserted into an inner chamber of an ampoule with relative ease due to its shorter length along the axial direction 204. The compressible portion 202, in this case the spring 202, is made of a material that enhances heat transfer from the ampoule to the solid precursor materials disposed on the tray 200. The spring 202 is in thermal contact with the wing portions 206, 208, which are heat-transfer components. Each of the wing portions 206, 208 includes respective curved surfaces 210, 212. The spring 202 is configured to push these curved surfaces 210, 212 away from each other such that the spring 202 enhances their contact with an inner wall surface of the ampoule. In some embodiments, all of the curved surfaces 210, 212 contacts at least a portion of the inner wall surface of the ampoule. According to some embodiments, the compressible portion 202 is not an accordion-like structure. The tray 200 includes component (e.g., a plate, bowl, trough, etc.) 214 for holding solid precursor materials. This component 214 has an upper surface 216. In some embodiments, the upper surface 216 is curved. The curved upper surface 216 can have a concave topology, a bowl-shape, or a trough-shape. The component 214 can have a single compartment or multiple compartments.

In a particular example, the tray 200 includes four modular components, the spring 202, a first wing portion 206, a second wing portion 208, a trough 214 with an upper surface 216 configured to hold solid precursor materials. The spring 202 is mechanically and frictionally engaged and connected to the wing portions 206, 208. Each wing portion 206, 208 has a retainer 218, 220 for connecting with the spring 202. This connection provides sufficient contact to transfer heat from the wing portions 206, 208 to the spring 202. Each of the wing portions 206, 208 has a horizontal component 222, 224 that connects with the trough 214, wherein the horizontal components 222, 224 are slidable with respect to the trough 214 and has a frictional engagement, a mechanical engagement, or both with the trough 214. The spring 202, when compressed and then released, causes the two wing portions 206, 208 to push away from each other. When the spring 202 is compressed, the spring potential energy is increased. That is, the spring potential energy of the spring 202 in the compressed state is higher than its relaxed state.

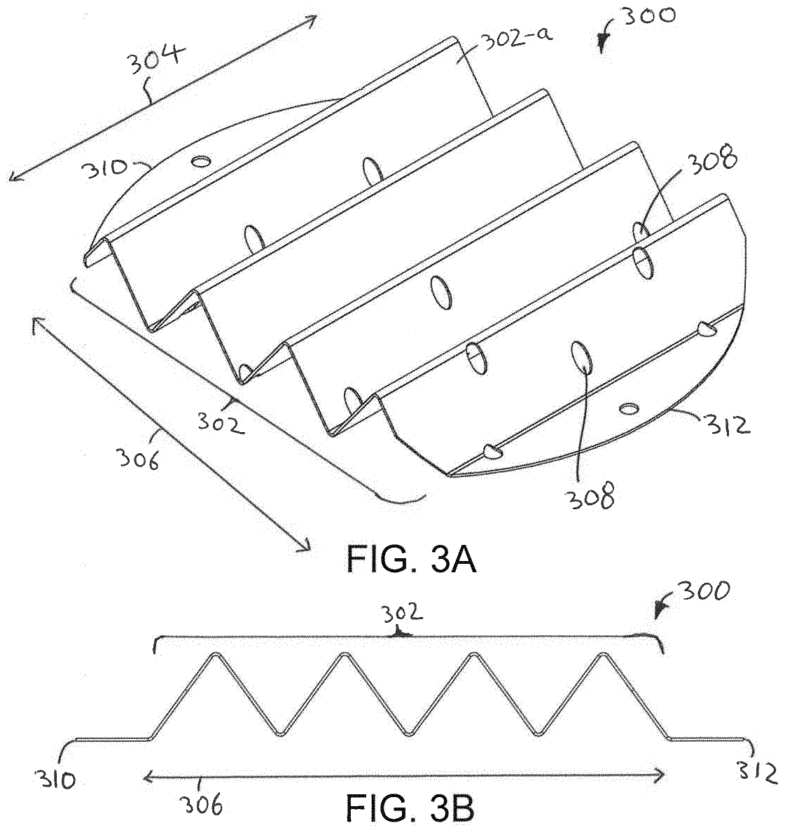

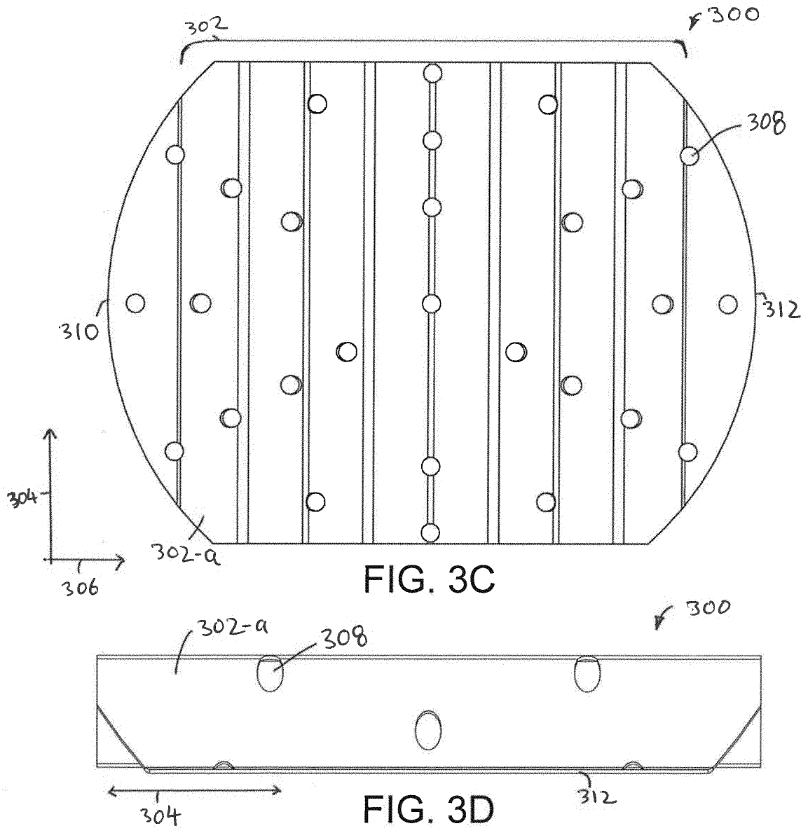

FIGS. 3A-3D show various views of a tray 300 according to some of the embodiments. FIG. 3A shows a perspective view; FIG. 3B shows a front view; FIG. 3C shows a top view; and FIG. 3D shows a side view of the tray 300. The tray 300 is a single unitary structure having an accordion-like structure 302, wherein the accordion-like structure 302 has a ridge direction 304 and a fold direction 306. The accordion-like structure 302 includes an accordion-like surface 302-a. In some embodiments, the surface 302-a is planar. In some embodiments, the surface 302-a is non-planar. In some embodiments, the surface 302-a includes planar portions and non-planar portions. The accordion-like structure 302 is compressible along the fold direction 306, but not along the ridge direction 304. The maximums and minimums of the accordion-like structure 302 is configured to have at least one surface for holding solid precursor materials. Further, the accordion-like structure 302 has a higher surface area to increase heat transfer from the tray to the solid precursor materials on the surface(s) of the tray 300. The tray 300 also has at least one passageway(s) 308 for fluid flow (e.g., flow of gas) when the tray 300 is installed within an ampoule. The tray 300 is also configured to be stackable with other trays of same or similar structure. The maximum(s) of one tray 300 can contact and/or connect to the minimum(s) of another tray when stacking a plurality of these trays 300. The outer surfaces 310, 312 at the ends of along the fold direction 306 are curved and configured to contact an inner wall surface(s) of the inner chamber of the ampoule. The accordion-like structure 302 allows the tray 300 to have a shorter length along the fold direction 306 for insertion into the ampoule, and then expand along the fold direction 306 to enhance and improve surface contact between the outer surfaces 310, 312 and the inner wall surface(s) of the inner chamber of the ampoule. That is, the accordion-like structure 302 causes the two outer surfaces 310, 312 to push away from each other when the compressed tray 300 is released. When the accordion-like structure 302 is compressed, the spring potential energy is increased. That is, the spring potential energy of the accordion-like structure 302 in the compressed state is higher than its relaxed state.

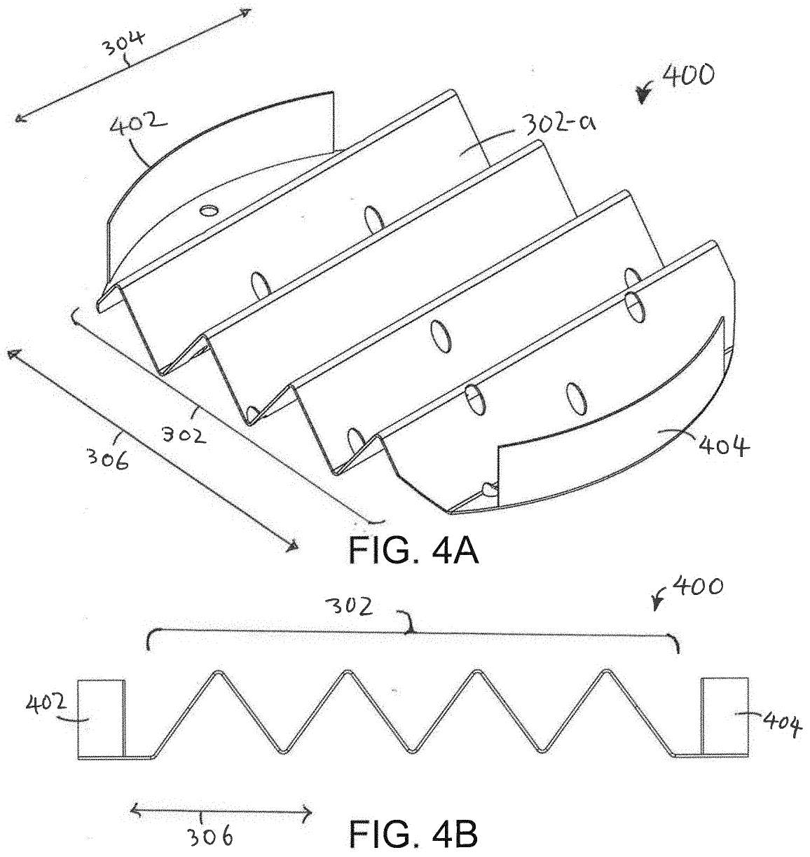

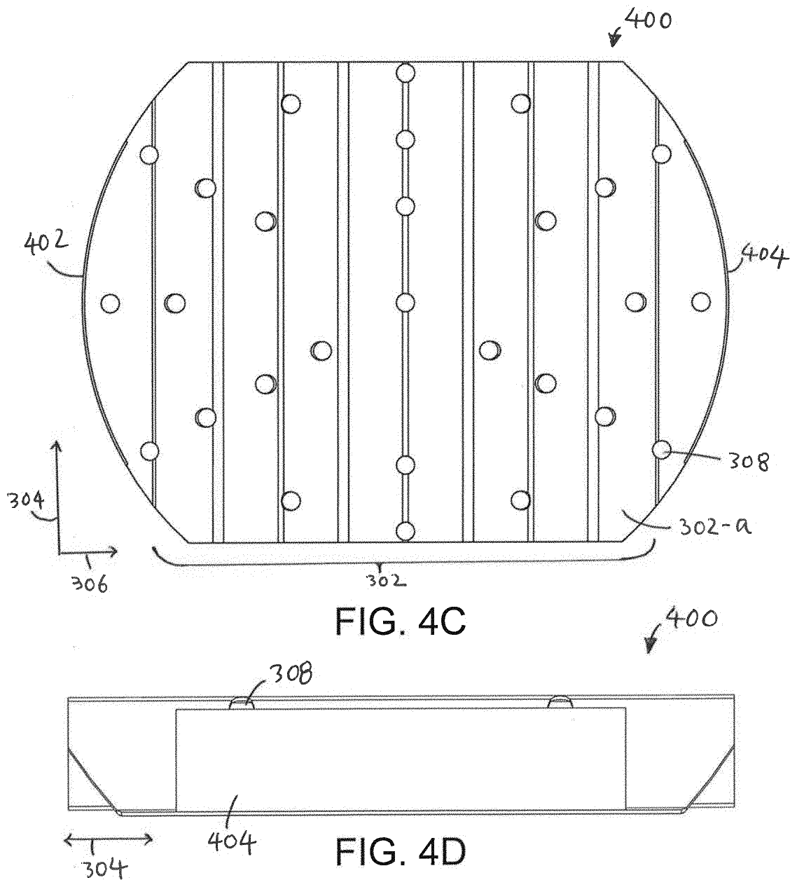

FIGS. 4A-4D show various views of another tray 400 according to some of the embodiments. FIG. 4A shows a perspective view; FIG. 4B shows a front view; FIG. 4C shows a top view; and FIG. 4D shows a side view of the tray 400. Tray 400 is similar to the tray 300 shown in FIGS. 3A-3D, but includes larger surface area components 402, 404 at the two outer regions when compared to the outer surfaces 310, 312 shown in FIGS. 3A-3D.

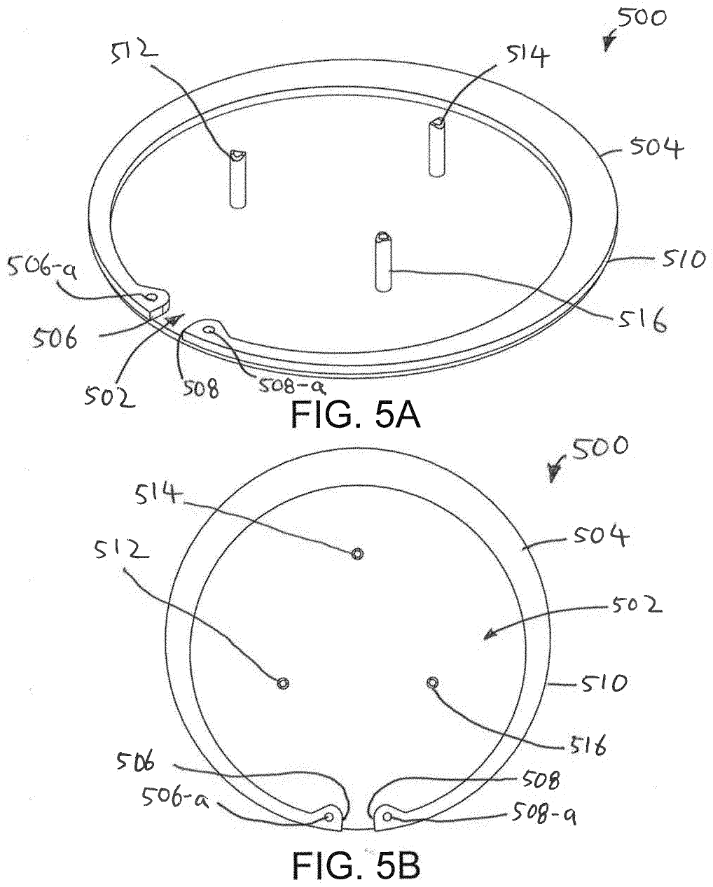

FIGS. 5A and 5B show various views of a tray 500 according to some of the embodiments. FIG. 5A shows a perspective view of the tray 500, and FIG. 5B shows the top view of the same tray 500. The tray 500 includes a planar plate 502 configured with an open-ring 504 component at the outer or outermost periphery thereof. The open-ring 504 is made of a material can provide thermal energy to the solid precursor materials disposed on the tray 500. The open-ring 504 is configured with a varying thickness of the ring-band to achieve a desired spring-constant property. The open-ring 504 can be compressed at the open ends 506, 508, thus reducing an overall size.

The open ends 506, 508 can be configured with additional structures (e.g., holes 506-a, 508-a) for mechanical, frictional, or both engagements to provide sufficient force for compressing the open-ring 504. That is, the open-ring 504 can be compressed to reduce along a radial direction of the open-ring 504. This allows the tray 500 to have a smaller planar profile for insertion into the ampoule. When this compressed state is released, the open-ring 504 expands along the radial direction, outward, to enhance and improve surface contact between the outer surface 510 of the tray 500 and the inner wall surface(s) of the inner chamber of the ampoule. When the open-ring 504 is compressed, the spring potential energy is increased. That is, the spring potential energy of the open-ring 504 in the compressed state is higher than its relaxed state. The tray 500 also includes flow paths 512, 514, 516, which are passageways for flowing a fluid, such as a gas, from bottom of the inner chamber to the top of the inner chamber, from the top of the inner chamber to the bottom of the inner chamber, or both.

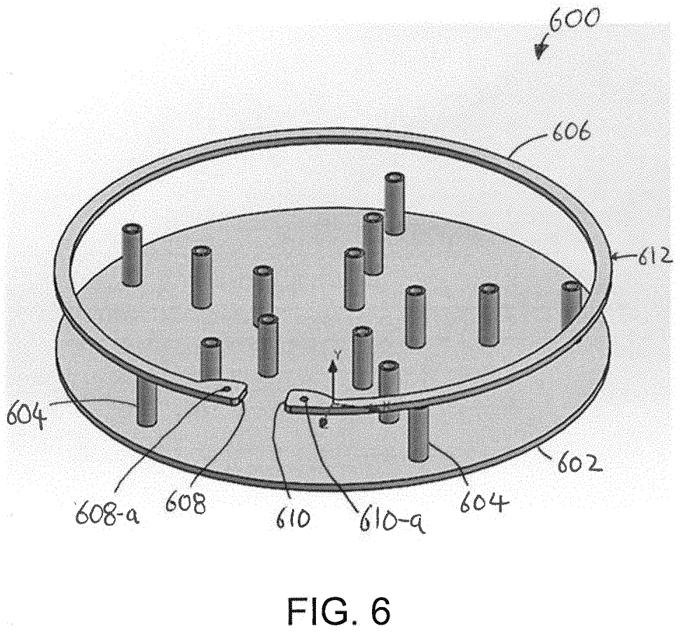

FIG. 6 shows an exploded view of a tray 600 according to some of the embodiments. The tray 600 includes a plate 602 configured to hold solid precursor materials. The plate 602 includes flow paths 604 which are passageways for flowing a fluid, such as a gas, from bottom of the inner chamber to the top of the inner chamber, from the top of the inner chamber to the bottom of the inner chamber, or both. The tray 600 further includes a compressible open-ring 606 (which can also be called a “snap ring” because when released from a compressed state, the ring “snaps” back to its original shape). The open-ring 606 can be placed above or below the plate 602. The open-ring 606 is made of a material can provide thermal energy to the solid precursor materials disposed on the tray 600. The open-ring 606 has open ends 608, 610, which can be configured with additional structures (e.g., holes 608-a, 610-a) for mechanical, frictional, or both engagements to provide sufficient force for compressing the open-ring 606. That is, the open-ring 606 can be compressed to reduce along a radial direction of the open-ring 606. This allows the tray 600 to have a smaller planar profile for insertion into the ampoule. When this compressed state is released, the open-ring 606 expands along the radial direction, outward, to enhance and improve surface contact between the outer surface 612 of the open-ring 606 and the inner wall surface(s) of the inner chamber of the ampoule. This allows for an improved thermal transfer from the inner wall surface of the ampoule to the open-ring 606. The open-ring 606 is in thermal contact with the plate 602. Thus, the improved thermal contact between the inner wall surface of the ampoule and the plate 602 is achieved by the open-ring 606. This also enhances thermal energy delivery to the solid precursor materials disposed on the plate 602. When the open-ring 606 is compressed, the spring potential energy is increased. That is, the spring potential energy of the open-ring 606 in the compressed state is higher than its relaxed state.

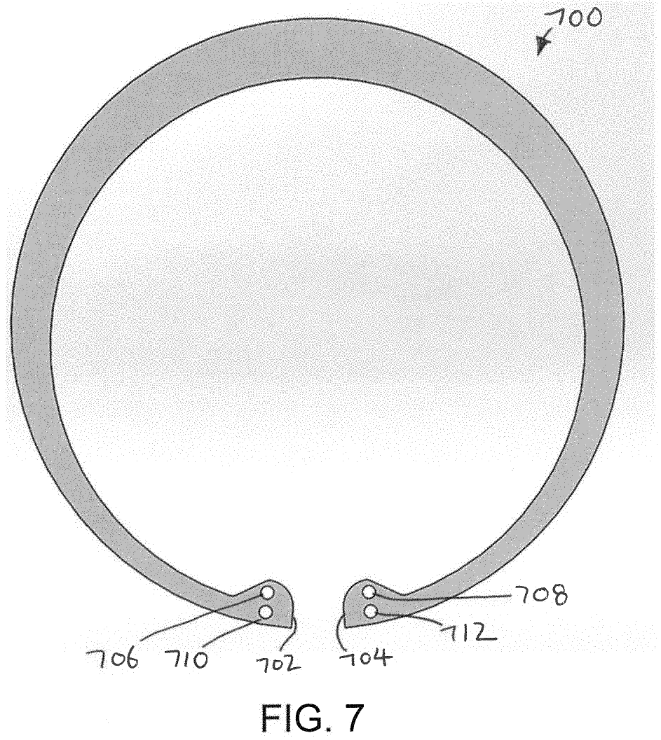

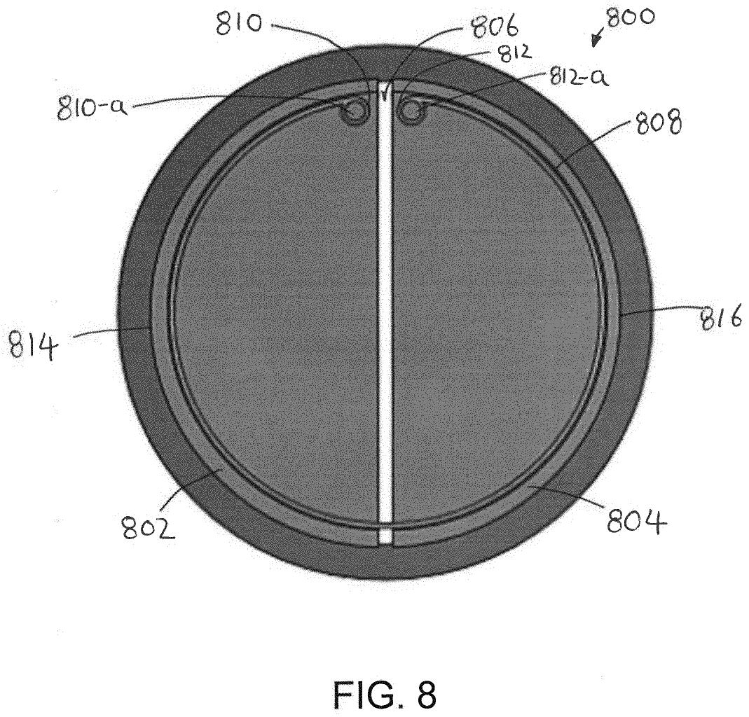

FIG. 7 shows an embodiment of a snap ring 700, which can be used with any of the trays shown in FIGS. 5A, 5B, and 6. The snap ring 700 is compressible, and when released from a compressed state, the open ring “snaps” back to its original shape. The snap ring 700 can be placed above or below a plate for the tray. The snap ring 700 is made of a material can provide thermal energy to the solid precursor materials disposed on the tray. The snap ring 700 has open ends 702, 704, which can be configured with additional structures, such as holes 706, 708, 710, 712 for mechanical, frictional, or both engagements to provide sufficient force for compressing the snap ring 700. One set of the holes, such as the inner holes 706, 708 can be used to compress the snap ring 700 with a tool, such as pliers or another mechanical device. The second set of holes, such as the outer pair of holes 710, 712 is configured to be used to secure the compressed snap ring using another tool, e.g., a wire. Once the wire is placed, the snap ring 700 can maintain its compressed configuration and be in a state so that the snap ring 700 could be easily inserted into a deep inner chamber of an ampoule. That is, the snap ring 700 can be compressed to reduce along a radial direction of the snap ring 700. This allows the tray to have a smaller planar profile for insertion into the ampoule. After the snap ring 700 (e.g., and the associated tray), is disposed in a desired location and position, the wire holding the compressed state can be cut to release the snap ring 700 against the inner dimensions of the inner chamber of the ampoule. When this compressed state is released via disengagement of the wire, the snap ring 700 expands along the radial direction, outward, to enhance and improve surface contact between the outer surface of the snap ring 700 and the inner wall surface(s) of the inner chamber of the ampoule. This allows for an improved thermal transfer from the inner wall surface of the ampoule to the snap ring 700. The snap ring 700 is in thermal contact with a plate. Thus, the improved thermal contact between the inner wall surface of the ampoule and the plate is achieved by the snap ring 700. This also enhances thermal energy delivery to the solid precursor materials disposed on the plate. When the snap ring 700 is compressed, the spring potential energy is increased. That is, the spring potential energy of the snap ring 700 in the compressed state is higher than its relaxed state.

FIG. 8 shows a top view of a tray 800 according to some of the embodiments. The tray 800 includes a plurality of plates 802, 804 configured to hold solid precursor materials. That is, each of the plates 802, 804 has respective first and second surfaces configured to hold solid procurators. Although FIG. 8 shows two plates 802, 804, more than two plates (and surfaces) can be incorporated into other modified embodiments of this tray 800. The plates 802, 804 are separated to define a flow path 806 which is a passageway for flowing a fluid, such as a gas, from bottom of the inner chamber to the top of the inner chamber, from the top of the inner chamber to the bottom of the inner chamber, or both. The tray 800 further includes a compressible open-ring 808 (which can also be called s “snap ring” because when released from a compressed state, the ring “snaps” back to its original shape). The open-ring 808 can be placed above or below the plates 802, 804. The open-ring 808 is made of a material that can provide thermal energy to the solid precursor materials disposed on the tray 800. The open-ring 808 has open ends 810, 812, which can be configured with additional structures (e.g., holes 810-a, 812-a) for mechanical, frictional, or both engagements to provide sufficient force for compressing the open-ring 808. That is, the open-ring 808 can be compressed to reduce along a radial direction, the circumferential portion, or both of the open-ring 808. This allows the plates 802, 804 to become closer together and the tray 800 attains a smaller planar profile for insertion into the ampoule. When this compressed state is released, the open-ring 808 “snaps back” and expands outward along the radial direction. This enhances and improves surface contact between the outer surfaces 814, 816 of the plates 802, 804 and the inner wall surface(s) of the inner chamber of the ampoule. This allows for an improved thermal transfer from the inner wall surface of the ampoule to the plates 802, 804. This also enhances thermal energy delivery to the solid precursor materials disposed on the plates 802, 804. When the open-ring 808 is compressed, the spring potential energy is increased. That is, the spring potential energy of the open-ring 808 in the compressed state is higher than its relaxed state.

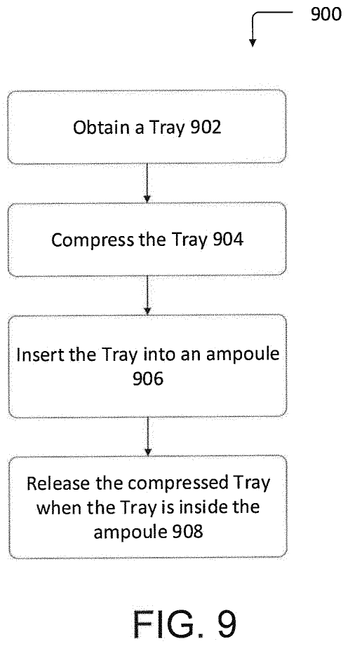

FIG. 9 shows an exemplary flowchart according to some of the embodiments of the method 900 for inserting a compressible tray into an ampoule of a system. The tray can be any of the trays having a compressible portion as described herein. The method 900 includes obtaining 902 a tray according to any of the embodiments described herein. Then, compressing 904 the tray, and inserting 904 the tray (now compressed) into an inner chamber which defines an inner volume of the ampoule. In some embodiments, the method 900 further comprises releasing 908 the compressible portion of the tray, wherein the compressible portion expands and the tray is configured to be in thermal contact with an inner wall surface of the ampoule. This can then lead to an expansion of the compressed tray to fit snugly and tightly to an inner wall surface of the inner chamber. The releasing 908 process can include, for example, cutting or releasing a wire holding a snap ring in a compressed state (e.g., see FIG. 7 and related description above).

The terminology used herein is intended to describe embodiments and is not intended to be limiting. The terms “a,” “an,” and “the” include the plural forms as well, unless clearly indicated otherwise. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that any of the embodiments or any portion(s) thereof may be combined with any of the other embodiments without departing from the scope of the present disclosure. It is also to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A tray for an ampoule, comprising:
a compressible portion having a compressed state and a relaxed state,
wherein a spring potential energy in the compressible portion is higher than in the relaxed state.

2. The tray of claim 1, further comprising:
a heat-transfer component,
wherein the heat-transfer component is in thermal contact with the compressible portion.

3. The tray of claim 2, further comprising:
a second heat-transfer component,
wherein the second heat-transfer component is in thermal contact with the compressible portion.

4. The tray of claim 3,
wherein a distance from the heat-transfer component to the second heat-transfer component is reduced when the compressible portion is compressed.

5. The tray of claim 3,
wherein the heat-transfer component and the second heat-transfer component are configured to be in thermal contact with an inner wall surface of the ampoule, and wherein the heat-transfer component and the second heat-transfer component are configured to transfer thermal energy from the inner wall surface of the ampoule to the compressible portion.

6. The tray of claim 1, further comprising:
a surface,
wherein the surface is configured to hold solid precursor materials, and
wherein the surface is in thermal contact with the compressible portion.

7. The tray of claim 6,
wherein the compressible portion is compressible along a radial direction of the surface, a circumferential portion of the surface, or both.

8. The tray of claim 6, wherein the surface includes a non-planar portion, a planar portion, or both.

9. The tray of claim 1,
wherein the compressible portion comprises a spring.

10. The tray of claim 1,
wherein the compressible portion comprises an accordion-like surface having a ridge direction and a fold direction.

11. The tray of claim 10,
wherein the accordion-like surface is configured to hold solid precursor materials.

12. The tray of claim 1,
wherein the compressible portion comprises an open-ring.

13. The tray of claim 12, further comprising:
a surface,
wherein the surface is configured to hold solid precursor materials, and
wherein the surface is in thermal contact with the open-ring.

14. The tray of claim 13, wherein the open-ring is disposed at an outer perimeter of the surface.

15. The tray of claim 13,
wherein the open-ring is disposed above the surface.

16. The tray of claim 13,
wherein the open-ring is disposed below the surface.

17. The tray of claim 13, further comprising:
a second surface,
wherein the second surface is configured to hold solid precursor materials, and
wherein the second surface is in thermal contact with the open-ring.

18. The tray of claim 17,
wherein a distance from the surface and the second surface is reduced when the compressible portion is compressed.

19. An ampoule, comprising:
the tray according to claim 1.

20. A method of inserting a tray into an ampoule, comprising:
obtaining the tray according to claim 1;
compressing the compressible portion of the tray; and
inserting the tray into an inner volume of the ampoule.
